(19) United States
(12) Patent Application Publication
(10) Pub. No.: US 2004/0141356 A1
(43) Pub. Date: Jul. 22, 2004

(54) Data communications method and apparatus

(76) Inventors: Maria Gabrani, Gattikon (CH); Andreas Herkersdorf, Inning a. Ammersee (DE)

Correspondence Address: IBM CORPORATION, INTELLECTUAL PROPERTY LAW DEPT., P . O . BOX 218, YORKTOWN HEIGHTS, NY, 10598, US

(21) Appl. No.: 10/650,316

(22) Filed: Aug. 28, 2003

(30) Foreign Application Priority Data
Aug. 29, 2002 (EP) 02405735.8

(51) Int. Cl. G11C 11/22

(52) U.S. Cl. 365/145

(57) ABSTRACT

The present invention provides a method and apparatus for altering the header having a layered structure of a frame in transit through a network node. Frame alteration commands issued by layer processing modules are assigned at relative positions with respect to the starting position of the layer. The relative positions with respect to each layer are further adjusted to adjusted relative positions in dependence on frame alteration commands previously assigned in the same layer. After translation of the adjusted relative positions to absolute positions, the frame alteration commands are executed sequentially by a frame alteration unit.

### TECHNICAL FIELD

The present invention generally relates to a method and apparatus for data communications and particularly relates to a method and apparatus for altering packet headers in transit through a network node.

### DESCRIPTION OF PRIOR ART

In a data communications network, a packet, also referred to as frame, may pass in transit through a number of intermediate network nodes on its course from a source node to a destination node. A task of the intermediate network nodes is to direct the packet on the appropriate path to its destination. Upon arrival of a packet at an intermediate network node, the packet is identified, its destination address is determined, its header is modified, and the packet is forwarded to the next network node. A simple and straightforward modification of the header may for example include setting a new MAC address and updating of checksums.

Traditionally, the information in a packet header is structured in layers relating to the layered functions of the OSI system, for example. As communications networks become larger and the procedure of forwarding packets becomes more content-aware and application-specific, the modifications of the packet header tend to involve an increasing number of layers of the OSI system. The following examples illustrate possible scenarios. IP forwarding may include modification or deletion of IP option fields along with the updating of the Time-to-Live field. In a load balancing system, swapping of transport layer UDP or TCP ports can be performed along with updating of sequence numbers. In a session-aware dispatcher of Secure Socket Layer connections, the session ID can be used to determine the forwarding of the packet, requiring updating the appropriate server node and the session ID to provide server node mapping.

Such deep packet processing and frame alteration is conventionally performed by software. However, as media speed increases and the tasks of an intermediate network node become increasingly complex, the migration of functionality from software to hardware becomes attractive.

The process of frame alteration is a prime candidate for migrating to hardware. Reasons for this are manifold: Frame alteration is a well-defined process performed on standard information fields of the packet header, and the alterations can be realized with simple functions such as Overlay, Insert, Delete, Add or And. Furthermore, frame alterations include the calculation of checksums which is more efficiently performed in hardware.

Systems that perform simple frame alterations in hardware are known. However, these implementations consider only lower layers of the OSI network model and perform the alteration requests based on unstructured flag signals on a predefined fixed logic. The IBM Network Processor reference IBM32NPR161EPXCAC133 is an example of such an implementation. A disadvantage associated with such implementations is that a change in communications standard or application will lead to a need for redesign of the frame alteration logic. Another disadvantage associated with such implementations is that an implementation capable of deep packet modifications will lead to complicated and inflexible logic. In U.S. Pat. No. 5,481,735 to Mortensen et al., a method for modifying packets that meet a particular criteria as the packets pass between two layers in a network is disclosed. In the method disclosed, however, the packet is modified every time the packet enters a new layer, thus precluding streamed execution of aggregated frame alteration commands in a single hardware unit.

In view of the continually changing demand for new communications standards and applications, as well as the increasing complexity of the tasks to be performed at media speed, it would be desirable to provide a frame alteration scheme allowing for a flexible assignment of frame alteration requests that can be executed sequentially in a single hardware unit.

### SUMMARY OF THE INVENTION

In accordance with the present invention, there is now provided a method for altering a header of an incoming frame entering a network node to a modified header (4) of an outgoing frame leaving the network node, the header having a layered structure, the method comprising the steps of: assigning frame alteration commands at relative positions with respect to the layered structure; adjusting the relative positions of the frame alteration commands to adjusted relative positions, in correspondence to previously assigned frame alteration commands with respect to the same layer; and, translating the adjusted relative positions to absolute positions for sequentially executing the frame alteration commands in a frame alteration unit.

In a preferred embodiment of the present invention, the step of translating is preferably performed in dependence on a packet information structure comprising layer starting positions and on content of the frame alteration commands. In a particularly preferred embodiment of the present invention, the step of adjusting is performed in dependence on content of the frame alteration commands. The method preferably comprises generating the layer starting positions by a parser unit. The method may also comprise appending further layer starting positions to the packet information structure by a processing unit. The frame alteration commands preferably comprise a respective layer number.

Viewing the present invention from another aspect, there is now provided apparatus for altering a header with layered structure of an incoming frame entering a network node to a modified header of an outgoing frame leaving the network node, the apparatus comprising: an assignment unit for assigning frame alteration commands at relative positions with respect to the layered structure; an adjustment unit for adjusting the relative positions of the frame alteration commands to adjusted relative positions, in correspondence to previously assigned frame alteration commands with respect to the same layer; and a translation unit for translating the adjusted relative positions to absolute positions for sequential execution of the frame alteration commands.

In a preferred embodiment of the present invention, the translation unit is responsive to a packet information structure comprising layer starting positions and to content of the frame alteration commands. The adjustment unit may be responsive to content of the frame alteration commands. The apparatus preferably comprises a parser unit for generating the layer starting positions. In a particularly preferred embodiment of the present invention, the apparatus comprises processing logic. The assignment unit, the adjustment unit and the translation unit may be implemented in the processing logic. In an especially preferred embodiment of the present invention, the apparatus comprises a frame alteration unit connected to the output of the processing logic for sequential execution of the frame alteration commands. The translation unit may be implemented in the frame alteration unit, and the assignment unit and the adjustment unit may be implemented in the processing logic. Alternatively, the translation unit and the adjustment unit may be implemented in the frame alteration unit, and the assignment unit may be implemented in the processing logic. The processing logic preferably comprises a plurality of processing units. The present invention also extends to a network node comprising such apparatus.

The partitioning of the frame alteration process into the steps of assigning, adjusting, and translating for sequential execution by a dedicated frame alteration unit leads to a flexible frame alteration scheme allowing a modular and independent design of corresponding hardware and/or software processing units that can be readily adapted to changes of the application. The assigning and adjusting can be performed in dependence on a packet information structure comprising a first list of layer starting positions and a second list of appended frame alteration commands thus allowing for a modular design of the processing units. Generating layer starting positions by a parser unit allows rapid access to the information contained in the layered header structure. Determination of additional layer starting positions and addition of such positions to the first list of the packet information structure by the processing units provides flexible handling of new header layers and the possibility of deep packet header alteration. The layer number in the frame alteration commands to specify the layer where the alteration is to be performed allows for a simple implementation of the steps of assigning and adjusting on a per layer basis.

### BRIEF DESCRIPTION OF THE DRAWINGS

Preferred embodiments of the invention will now be described, by way of example only, with reference to the accompanying drawings, in which:

FIG. 1 is a block diagram of a network node embodying the present invention;

FIG. 2 is a another block diagram of a network node embodying the present invention in which there is provided a parser unit, processing units, a frame alteration unit, and the accompanying signals representing incoming frame, packet information structure, and outgoing frame;

FIG. 3 is a block diagram of a signal representing an incoming frame with a layered header structure and the starting positions of each layer;

FIG. 4 is a block diagram of a frame alteration command;

FIG. 5 is a block diagram of a signal representing an incoming frame with layered header structure, header information fields marked for deletion or insertion by frame alteration commands, the relative positions of the header information fields with respect to the starting position of each layer, and their corresponding adjusted relative positions; and,

FIG. 6 shows, from top to bottom, information fields marked for deletion or insertion by frame alteration commands with their translated absolute positions for sequential execution by the frame alteration unit, and the resulting outgoing frame with modified header.

### DETAILED DESCRIPTION OF THE INVENTION

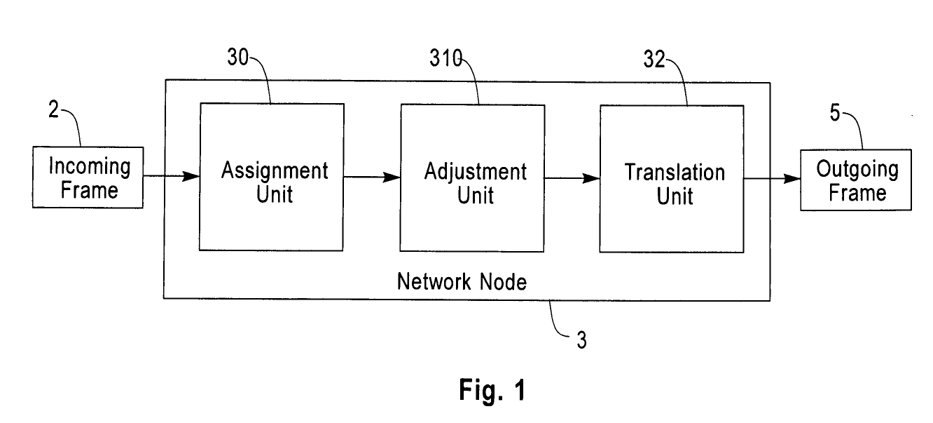

Referring first to FIG. 1, in a preferred example of a network node 3 embodying the present invention, there is provided apparatus for altering a header with a layered structure of an incoming frame entering a node 3 to a modified header of an outgoing frame 5 leaving the node. The apparatus comprises an assignment unit 30, an adjustment unit 31, and a translation unit 32. These units 30-32 may be implemented in hardware, software, a a combination of both hardware and software. In operation, the assignment unit 30 assigns frame alteration commands at relative positions with respect to the layered structure. The adjustment unit 31 adjusts the relative positions of the frame alteration commands to adjusted relative positions, in correspondence to previously assigned frame alteration commands with respect to the same layer. The translation unit 32 for translating the adjusted relative positions to absolute positions for sequential execution of the frame alteration commands. The translation unit 32 is responsive to a packet information structure comprising layer starting positions and to content of the frame alteration commands. The adjustment unit is responsive to content of the frame alteration commands. The frame alteration commands comprise a respective layer number.

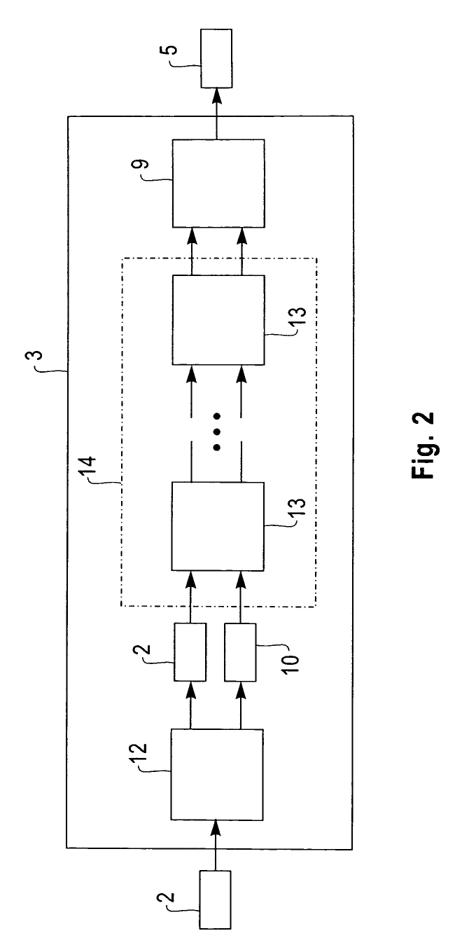

Referring now to FIG. 2, in a particularly preferred example of a network node embodying the present invention, there is provided a parser unit 12 for generating the layer starting positions, along with processing logic 14. The processing logic 14 comprises a plurality of processing units 13. A frame alteration unit 9 is connected to the output of the processing logic 14 for sequential execution of the frame alteration commands. As will be described shortly, the assignment unit 30, the adjustment unit 31, and the translation unit 32 herein before described with reference to FIG. 1 may be implemented by such processing logic 14. Alternatively, the translation unit 32 may be implemented in the frame alteration unit 9, with the assignment unit 30 and the adjustment unit 31 implemented in the processing logic 14. In another alternative, the translation unit 32 and the adjustment unit 31 may be implemented in the frame alteration unit 9, with the assignment unit 30 implemented in the processing logic 14.

As indicated earlier, the processing logic 14 comprises a plurality of processing units 13. The units 9, 12, and 13 are connected as follows. The parser unit 12 receives an incoming frame 2 entering the network node 3. The incoming frame 2 is further passed through the processing units 13 and is received by the frame alteration unit 9. A packet information structure 10 originating from the parser unit 12 is also passed through the processing units 13 and is received by the frame alteration unit 9. The frame alteration unit 9 then transmits an outgoing frame 5 leaving the network node 3.

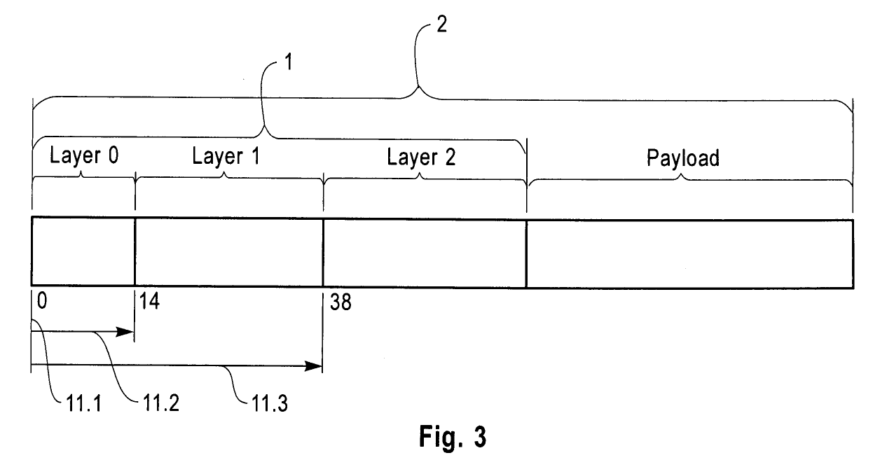

Referring now to FIG. 3, the structure of the incoming frame 2 comprising a header 1 and a payload is shown therein. The header 1 is structured into layers denoted here with layer 0, layer 1, and layer 2. Here, only three layers out of the seven layers defined in the OSI reference system are shown. Layer starting positions 11.1-11.3 indicate the start of each layer with respect to the start of the header 1 in units of bits or bytes and are determined in the parser unit 12. Here, the measure of position and length, without loss of generality, is chosen as bytes. Hence, by way of example, the first starting position 11.1 indicating the start of layer 0 having a value 0, the second starting position 11.2 indicating the start of layer 1 having a value 14, and the third starting position 11.3 indicating the start of layer 2 having a value 38 is shown. The layer starting positions 11.1-11.3 are then assembled in a first list and inserted in the packet information structure 10 by the parser unit 12.

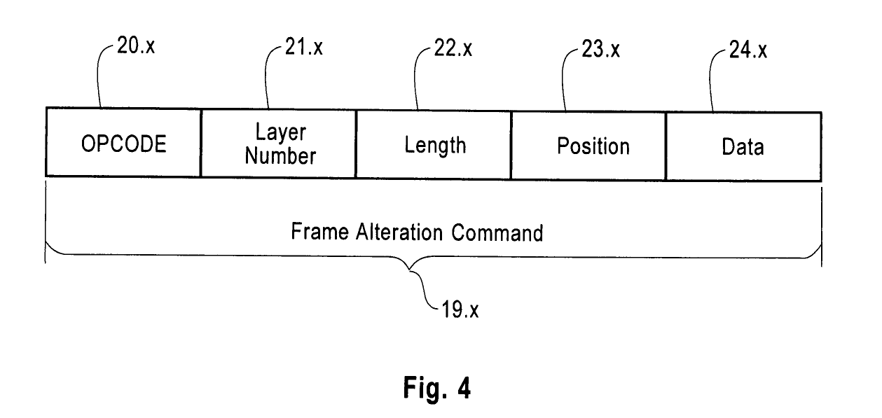

FIG. 4 shows the structure of a frame alteration command 19.x. The frame alteration command 19.x comprises an operation code 20.x, also referred to as an opcode, specifying the modification to be performed, a layer number field 21.x specifying the layer where the modification is performed, a length field 22.x, a position field 23.x, and a data field 24.x.

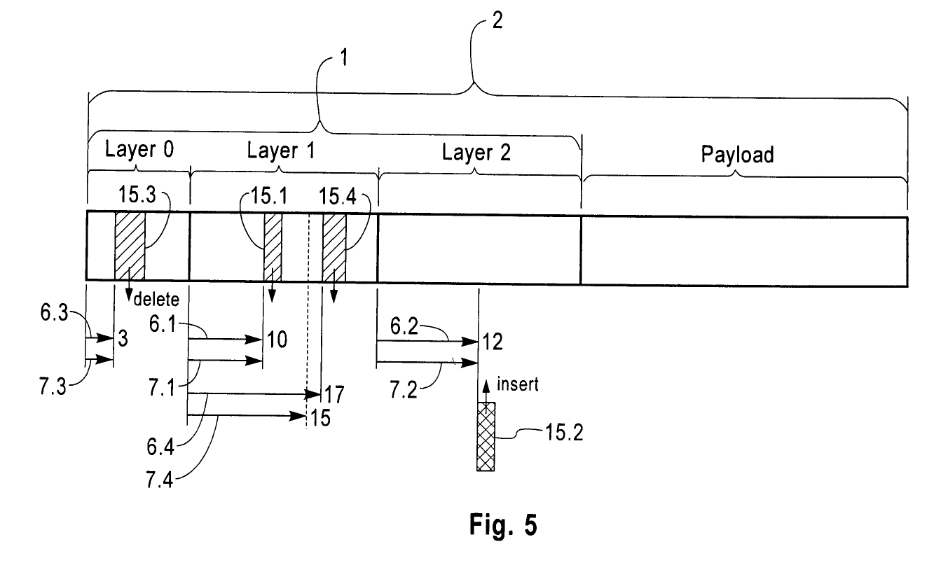

Referring to FIG. 5, the length field 22.x specifies the length of a modified information field 15.x. The position field 23.x specifies, in the step of assigning, the relative position 6.x of, and in the step of adjusting, the adjusted relative position 7.x of, the information field 15.x. The data field 24.x specifies the content of the information field 15.x.

Returning to FIG. 4, the frame alteration commands 19.x are assigned by the processing units 13 in dependence on the information content of the header 1.

In a preferred embodiment of the present invention, a method for frame alteration comprises the steps of assigning, adjusting, and translating frame alteration commands 19.x for sequential execution in the frame alteration unit 9. The steps of assigning, adjusting, and translating are performed by the assignment unit 30, the adjustment unit 31, and the translation unit 32 respectively. As indicated earlier, these units 30-32 may be implemented by the processing logic 14 or by a combination of the processing logic 14 and the frame alteration unit 9.

Referring again to FIG. 5, the step of assigning is described here, by way of example, as involving four frame alteration commands 19.1-19.4 being assigned by processing units 13.

The first frame alteration command 19.1 requests the deletion of an information field 15.1 in layer 1. The frame alteration command 19.1 with opcode 20.1 specifying the operation of deletion thus contains: in the layer number field 21.1, the layer number 25.1 having a value 1; in the length field 22.1, the length of the information field 15.1 having a value 2; and, in the position field 23.1, the relative position 6.1 having a value 10 with respect to the start of the corresponding layer. The data field 24.1 is marked as not applicable. The alteration command 19.1 is then inserted in the format of a second list in the packet information structure 10.

The second frame alteration command 19.2 requests the insertion of an information field 15.2 in layer 2. The frame alteration command 19.2 with opcode 20.2 specifying the operation of insertion thus contains: in the layer number field 21.2, the layer number 25.2 having a value 2; in the length field 22.2, the length of the information field 15.2 having a value 1; in the position field 23.2, the relative position 6.2 having a value 12 with respect to the start of the corresponding layer; and, in the data field 24.2 one byte of data. The frame alteration command 19.2 is then appended to the second list in the packet information structure 10.

The third frame alteration command 19.3 requests the deletion of an information field 15.3 in layer 0. The frame alteration command 19.3 with opcode 20.3 specifying the operation of deletion thus contains: in the layer number field 21.3, the layer number 25.3 having a value 0; in the length field 22.3, the length of the information field 15.1 having a value 5; and, in the position field 23.3, the relative position 6.3 having a value 3 with respect to the start of the corresponding layer. The data field 24.3 is marked as not applicable. The frame alteration command 19.3 is then appended to the second list in the packet information structure 10.

The fourth frame alteration command 19.4 again requests the deletion of an information field 15.4 in layer 1. The frame alteration command 19.4 with opcode 20.4 specifying the operation of deletion thus contains: in the layer number field 21.4, the layer number 25.4 having a value 1; in the length field 22.4, the length of the information field 15.4 having a value 3; and, in the position field 23.4, the relative position 6.4 having a value 17 with respect to the start of the corresponding layer. The data field 24.4 is marked as not applicable. The frame alteration command 19.4 is then appended to the second list in the packet information structure 10.

The step of adjusting involves adjusting the relative positions 6.1-6.4 to adjusted relative positions 7.1-7.4 on a per layer basis in correspondence to previously assigned alteration commands 19.1-19.4. In other words, the adjusted relative positions 7.1-7.4 reflect the shift of the relative positions 6.1-6.4 on a per layer basis in correspondence to frame alteration commands 19.1-19.4 requesting the insertion or deletion of information fields 15.1-15.4.

By way of example, and considering the assigned frame alteration commands 19.1-19.4, the following values of the adjusted relative positions 7.1-7.4 are obtained. With respect to layer 0, the frame alteration command 19.3 leads to the adjusted relative position 7.3 having a value 3, which is the same as the relative position 6.3 having a value 3.

With respect to layer 1, the assigned frame alteration commands 19.1 and 19.4 request deletion of information fields 15.1, and 15.4, respectively. Here, the step of adjusting leads to the adjusted relative position 7.1 having a value 10, which is the same as the relative position 6.1 having a value 10, and to the adjusted relative position 7.4 having a value 15. In other words, the relative position 6.4 having a value 17 as indicated in the position field 23.4 is left-shifted to the adjusted relative position 7.4 having a value of 17−2=15, thus reflecting the anticipated deletion of information field 15.1 having a length value 2 as indicated in the length field 22.1.

With respect to layer 2 the assigned frame alteration command 19.2 leads to the adjusted relative position 7.2 having a value 12, which is the same as the relative position 6.2 having a value 12.

An anticipated insertion of an information field 15.x may cause a right-shift in dependence on previously assigned alteration commands 19.x. It is also to be appreciated that the assignment of a frame alteration command 19.x with opcode 20.x denoting operations such as AND or OR may not require the step of adjusting.

The step of adjusting may be performed concurrently with each frame alteration command assigned.

The step of translating involves the translation of the adjusted relative positions to absolute positions with respect to the start of the header for sequential execution of the frame alteration commands in the frame alteration unit. By way of example, the stages of sequential translation and execution are described herein as follows.

In an initial stage, the layer starting positions 11.1-11.3 contained in the first list are stored in a register (not shown). The register thus contains layer starting positions 11.1, 11.2, and 11.3 having values 0, 14, and 38, respectively.

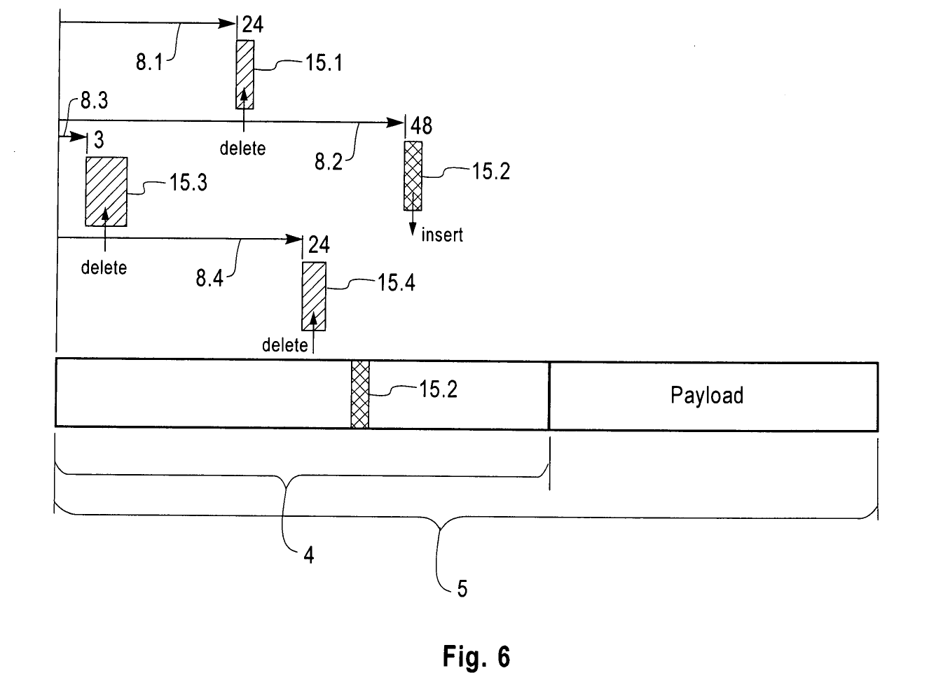

Referring to FIG. 6, in a following stage, the first frame alteration command 19.1 is interpreted and the value of the absolute position 8.1 is determined by adding the values of layer starting position 11.2 and adjusted relative position 7.1, yielding a value 14+10=24, as shown in FIG. 5. The register is updated with the shifted layer starting positions 11.1, 11.2, and 11.3 now having values 0, 14, and 36 (38−2), respectively. The frame alteration command 19.1 is then executed by deleting the information field 15.1 from the header 1.

In a following stage, the second frame alteration command 19.2 is interpreted and the value of the absolute position 8.2 is determined by adding the values of layer starting position 11.3 and adjusted relative position 7.2, yielding a value of 36+12=48. The register is updated with the shifted layer starting positions 11.1, 11.2, and 11.3 now having values 0, 14, and 36, respectively. The frame alteration command 19.2 is then executed by inserting the information field 15.2 in the header 1.

In a following stage, the third frame alteration command 19.3 is interpreted and the value of the absolute position 8.3 is determined by adding the values of layer starting position 11.1 and adjusted relative position 7.3, yielding a value of 0+3=3. The register is updated with the shifted layer starting positions 11.1, 11.2, and 11.3 now having values 0, 9 (14−5), and 31 (36−5), respectively. The frame alteration command 19.3 is then executed by deleting the information field 15.3 in the header 1.

In a following stage, the fourth and last frame alteration command 19.4 is interpreted and the value of the absolute position 8.4 is determined by adding the values of layer starting position 11.2 and adjusted relative position 7.4, yielding a value of 9+15=24. The register is updated with the shifted layer starting positions 11.1, 11.2, and 11.3 now having values 0, 9, and 28 (31−3), respectively. The frame alteration command 19.4 is then executed by deleting the information field 15.4 in the header 1. FIG. 5 further shows the resulting outgoing frame 5 with modified header 4.

In a particularly preferred embodiment of the present invention, processing units 13 may append further starting positions 11.x to the first list in the packet information structure 10 in dependence on frame alteration commands 19.x assigned in layers not previously parsed in the parser unit 12.

In another embodiment of the present invention, the frame alteration unit 9 may order the frame alteration commands in ascending or descending order so that final execution is performed in a progressive manner.

It will be appreciated that any embodiment of the present invention described herein may be combined with one or more of the other embodiments of the present invention described herein. It will also be appreciated that the parser unit 12, processing logic 14, and frame alteration unit 9 may be implemented by hardwired circuitry, computer program code, or by hardwired circuitry and computer program code in combination. Other embodiments of the present invention will be apparent to those skilled in the art.

1. A method for altering a header of an incoming frame entering a network node to a modified header of an outgoing frame leaving the network node, the header having a layered structure, the method comprising the steps of:
assigning frame alteration commands at relative positions with respect to the layered structure;
adjusting the relative positions of the frame alteration commands to adjusted relative positions, in correspondence to previously assigned frame alteration commands with respect to the same layer; and,
translating the adjusted relative positions to absolute positions for sequentially executing the frame alteration commands in a frame alteration unit.

2. A method as recited in claim 1, wherein the step of translating is performed in dependence on a packet information structure comprising layer starting positions and on content of the frame alteration commands.

3. A method as recited in claim 2, wherein the step of adjusting is performed in dependence on content of the frame alteration commands.

4. A method as recited in claim 2, comprising generating the layer starting positions by a parser unit.

5. A method as recited in claim 2, comprising appending further layer starting positions to the packet information structure by a processing unit.

6. A method as recited in claim 1, wherein the frame alteration commands comprise a respective layer number.

7. An apparatus for altering a header with layered structure of an incoming frame entering a network node to a modified header of an outgoing frame leaving the network node, the apparatus comprising:
an assignment unit for assigning frame alteration commands at relative positions with respect to the layered structure;
an adjustment unit for adjusting the relative positions of the frame alteration commands to adjusted relative positions, in correspondence to previously assigned frame alteration commands with respect to the same layer; and
a translation unit for translating the adjusted relative positions to absolute positions for sequential execution of the frame alteration commands.

8. An apparatus as recited in claim 7, wherein the translation unit is responsive to a packet information structure comprising layer starting positions and to content of the frame alteration commands.

9. An apparatus as recited in claim 8, wherein the adjustment unit is responsive to content of the frame alteration commands.

10. An apparatus as recited in claim 8, comprising a parser unit for generating the layer starting positions.

11. An apparatus as recited in claim 8, wherein the frame alteration commands comprise a respective layer number.

13. An apparatus as recited in claims 8, comprising processing logic.

14. An apparatus as recited in claim 13, wherein the assignment unit, the adjustment unit and the translation unit are implemented in the processing logic.

15. An apparatus as recited in claim 13, comprising a frame alteration unit connected to the output of the processing logic for sequential execution of the frame alteration commands.

16. An apparatus as recited in claim 15, wherein the translation unit is implemented in the frame alteration unit, and the assignment unit and the adjustment unit are implemented in the processing logic.

17. An apparatus as recited in claim 16, wherein the translation unit and the adjustment unit are implemented in the frame alteration unit, and the assignment unit is implemented in the processing logic.

18. An apparatus as recited in claim 13, wherein the processing logic comprises a plurality of processing units.

19. A program storage device readable by a digital pocessing apparatus and having a program of instructions which are tangibly embodied on the storage device and which are executable by the processing apparatus to perform a method of altering a header of an incoming frame of network node to a modified header of an outgoing frame, the method comprising:
assigning frame alteration commands at relative positions with respect to the layered structure;
adjusting the relative positions of the frame alteration commands to adjusted relative positions, in correspondence to previously assigned frame alteration commands with respect to the same layer; and
translating the adjusted relative positions to absolute positions for sequentially executing the frame alteration commands in a frame alteration unit.
